(19) United States
(12) Patent Application Publication
(10) Pub. No.: US 2026/0358414 A1
(43) Pub. Date: Nov. 12, 2026

(54) Enhanced Memory-Channel-Focused Scandump

(71) Applicant: Google LLC, Mountain View, CA (US)

(72) Inventors: Anshuman Mishra, Bangalore (IN); Pandithurai Sangaiyah, Bangalore (IN); Jenkai Cho, Taichung (TW)

(73) Assignee: Google LLC, Mountain View, CA (US)

(21) Appl. No.: 19/201,534

(22) Filed: May 7, 2025

(51) Int. Cl. G01R 31/3185; G01R 31/317

(52) U.S. Cl. CPC G01R 31/318544; G01R 31/31705; G01R 31/318558

(57) ABSTRACT

Typically, scandump data for debugging efforts is obtained from an integrated circuit using specialized testing equipment, which is infeasible for a deployed electronic device. Instead, the scandump data can be stored in a local memory of the device. If the device interleaves data across multiple memory channels, however, extraction of the scandump data becomes riskier or more difficult. Further, interleaving scandump data can waste 75% of the reserved memory space (e.g., with four memory channels). To enhance a scandump operation in a memory interleaving environment, memory is partitioned into first and second regions with different first and second interleaving granularities (IGs). The first IG is sufficiently large to encompass targeted scandump data. Accordingly, a memory interleaver can transfer the scandump data to the memory of one memory channel without interleaving based on a first-region segment allocated to the one memory channel. Other first-region segments can be used for other purposes.

### BACKGROUND

Computing and other electronic devices play integral roles in manufacturing, communication, transportation, healthcare, commerce, social interaction, entertainment, and other services. For example, electronic devices power the server farms that provide cloud-based, distributed computing functionality for commerce, communication, and large-model or high-demand artificial intelligence (AI) technologies. Electronic devices are also embedded in many different types of modern equipment, from medical devices to appliances and from vehicles to industrial tools. Personal electronic devices enable portable video viewing, convenient smart digital assistants, and access to local and remote AI services. Additionally, one versatile electronic device—the smartphone—has practically become a necessity to have within arm's reach.

Software executes on electronic devices to perform some intended functionality, such as providing communication, entertainment, or financial services. To operate effectively, the software is tested on the targeted hardware in various scenarios and under different parameters. Initially, the testing is performed in a laboratory or production facility. Such testing locations include specialized debugging equipment to facilitate thorough testing. Many electronic devices, however, are ultimately deployed or operated outside of such testing locations. Unfortunately, even with an extensive software-testing regime, the interaction between hardware and software is sufficiently complex that software execution issues can arise once an electronic device is deployed in the field.

### SUMMARY

This document describes hardware and techniques that enable a scandump operation to be performed in a focused manner using one or more memory channels, including using as few as a single memory channel. For example, scandump data can be transferred to a single memory channel of multiple memory channels even in a memory interleaving environment. Duplication of the scandump data to other memory channels can be avoided. Further, memory space need not be set aside for the other memory channels and remain unused. Thus, certain described implementations enable an efficient transfer of scandump data to a single memory channel while an electronic device is in the field and without relying on specialized testing equipment.

Generally, this document describes mechanisms that enable the storing of scandump data to be focused on fewer than all memory channels of a system with multiple memory channels. As part of a debugging process or recovery from an error, a processing system, such as a system-on-chip (SoC), can perform a scandump operation that produces scandump data. The scandump data represents the logical state of circuitry at the time of interest, which may be a scheduled time for testing or debugging purposes or may be a time that arises due to a processing error or operational fault. The scandump data serves as a snapshot of executing software at that moment of interest.

If external testing equipment is available, the scandump data can be output to the testing equipment in a serialized fashion in accordance with an industry standard without separate storage at the device including the SoC. In the field, however, the SoC at least temporarily relies on local storage, such as dynamic random-access memory (DRAM) that is part of or coupled to the SoC. Unfortunately, using this local storage becomes problematic in systems with multiple memory channels. Systems that include multiple memory channels interleave data across the multiple channels to increase memory-accessing bandwidth. If the scandump data is interleaved across multiple memory channels such that multiple complete copies of the scandump data are produced, reserved memory space is wasted with the multiple copies, and extracting the stored scandump data is difficult even though a copy can be obtained using only one memory channel. If the scandump data is interleaved across multiple memory channels to instead produce a single interleaved copy, the process of extracting the stored scandump data is complicated and time consuming. Further, if just one of the multiple memory controllers is malfunctioning, then the stored scandump data is incomplete and ineffective for debugging purposes.

To address these issues, in example implementations, a system partitions an address space of the memory into multiple regions and institutes different interleaving granularities in each region. For example, a first region has a first interleaving granularity (IG), and a second region has a second interleaving granularity. The first interleaving granularity is sufficiently large to encompass a targeted instance of scandump data. The second interleaving granularity can be set to facilitate high-bandwidth accessing of regular data that is stored across the multiple memory channels. Each region can further be partitioned into multiple segments, such as one segment per memory channel. The segments can “inherit” the interleaving granularity of the region of which it forms a part. For segments of the first region, each first-region segment can be allocated a size that is at least equal to the first interleaving granularity.

In example operations, when a scandump is triggered, the scandump data can be directed to a particular memory channel that is assigned to a particular first-region segment that was partitioned from the first region. With the first interleaving granularity larger than the size of the scandump data, the entire scandump data is transferred to the particular memory channel. The other first-region segments can still store data during regular operations but at a lower memory-accessing bandwidth due to the likely absence of interleaving. The second interleaving granularity can be appreciably smaller than the first interleaving granularity, such as by being three or more orders of magnitude smaller. The second interleaving granularity can correspond, for instance, to a standard interleaving granularity for the system that supports efficient, high-bandwidth memory transfers. Multiple second-region segments, which are partitioned from the second region, therefore enable high-bandwidth memory transfers to each of the multiple channels, including across the multiple channels using an interleaving technique.

Thus, in some implementations, by focusing the transfer of scandump data on a selected memory controller, the memory space that is carved out for scandump operations can be reduced by at least the size of the carve-out space multiplied by the quantity of memory controllers that are not responsible for storing the scandump data. Additionally or alternatively, described implementations can increase the debug visibility of software into the operations of the memory controllers by freeing at least one memory controller to participate in a scandump operation of the logic that forms the memory controller. This enables testers to debug failures originating from memory controllers without a dependency on specialized test equipment. By storing a contiguous, non-interleaved copy of the scandump data in a selected memory controller, retrieval of the scandump data is also simplified. Other advantages are described herein.

In example implementations, a method for implementing a scandump operation using at least one memory channel is described. The method includes partitioning a logical address space into a first region and a second region. The method also includes instituting a first interleaving granularity for the first region and a second interleaving granularity for the second region, with the first interleaving granularity different from the second interleaving granularity. The method additionally includes partitioning the first region into multiple first-region segments, with each respective first-region segment of the multiple first-region segments corresponding to a respective memory channel of multiple memory channels. The method also includes assigning a first first-region segment of the multiple first-region segments to a first memory channel of the multiple memory channels. The method further includes transferring scandump data to the first memory channel based on the first first-region segment and in accordance with the first interleaving granularity.

In example implementations, an apparatus for implementing a scandump operation using at least one memory channel is described. The apparatus includes multiple memory channels and at least one memory configured to store processor-executable instructions. The apparatus also includes one or more processors coupled to the multiple memory channels and the at least one memory. The one or more processors are configured to execute the processor-executable instructions to partition a logical address space into a first region and a second region and to partition the first region into multiple first-region segments. Each respective first-region segment of the multiple first-region segments corresponds to a respective memory channel of the multiple memory channels. The one or more processors are also configured to assign a first first-region segment of the multiple first-region segments to a first memory channel of the multiple memory channels. The one or more processors are additionally configured to institute a first interleaving granularity for the first region and a second interleaving granularity for the second region, with the first interleaving granularity different from the second interleaving granularity. The one or more processors are further configured to transfer scandump data to the first memory channel based on the first first-region segment and in accordance with the first interleaving granularity.

In example implementations, an apparatus for implementing a scandump operation using at least one memory channel is described. The apparatus includes multiple memory channels including a first memory channel and a second memory channel. The apparatus also includes one or more processors coupled to the multiple memory channels. The one or more processors are configured to partition a logical address space into a first region and a second region. The first region has multiple first-region segments, and the second region has multiple second-region segments. The one or more processors are also configured to store non-scandump data into the first memory channel based on a first first-region segment of the multiple first-region segments and in accordance with a first interleaving granularity corresponding to the first region. The one or more processors are additionally configured to store data into the multiple memory channels in an interleaved manner based on multiple second-region segments and in accordance with a second interleaving granularity corresponding to the second region. The first interleaving granularity is different from the second interleaving granularity. The one or more processors are further configured to transfer scandump data into the second memory channel based on a second first-region segment of the multiple first-region segments and in accordance with the first interleaving granularity corresponding to the first region. Other implementations are described herein.

### BRIEF DESCRIPTION OF DRAWINGS

Apparatuses of and techniques for enhanced memory-channel-focused scandump are described with reference to the following drawings. The same numbers are used throughout the drawings to reference like features and components.

FIG. 1 illustrates an example apparatus with logic and multiple memory channels that can implement enhanced memory-channel-focused scandump.

FIG. 2 is an example schematic diagram illustrating a memory interleaver, circuitry that can realize at least one instance of logic, and multiple memory channels that can jointly implement enhanced memory-channel-focused scandump.

FIG. 3 is an example schematic diagram illustrating memory interleaving across multiple memory channels in accordance with enhanced memory-channel-focused scandump.

FIG. 4 is a schematic diagram illustrating example approaches to partitioning a memory address space into multiple regions and multiple segments with the approaches involving multiple interleaving granularities (IGs) in accordance with enhanced memory-channel-focused scandump.

FIG. 5 is an example schematic diagram illustrating memory interleaving across multiple memory channels with respect to a first region having a first interleaving granularity (IG) in accordance with enhanced memory-channel-focused scandump.

FIG. 6 is an example schematic diagram illustrating memory interleaving across multiple memory channels with respect to a second region having a second interleaving granularity (IG) in accordance with enhanced memory-channel-focused scandump.

FIG. 7 is an example sequence diagram for performing a scandump operation that is focused on at least one memory channel of multiple memory channels in accordance with enhanced memory-channel-focused scandump.

FIG. 8 is a flow chart illustrating an example process for enhanced memory-channel-focused scandump.

FIG. 9 is a flow diagram illustrating an example process for enhanced memory-channel-focused scandump.

FIG. 10 illustrates various components of an example electronic device that can implement enhanced memory-channel-focused scandump in accordance with one or more described aspects.

### DETAILED DESCRIPTION

### Overview

Electronic devices provide features and perform functions to make important contributions to modern society, such as those related to communication, safety, manufacturing, content creation, and information technology generally. These contributions depend, at least partially, on software that functions correctly on the underlying hardware. To increase the likelihood of correct software functioning, the software can be tested on the targeted hardware for which the software is developed. This document describes logic and techniques that enable software to be debugged more efficiently or more completely in the absence of specialized testing equipment.

Robust software debug visibility is important for tackling the complexity of modern electronic devices, such as mobile devices with system-on-chips (SoCs). Thorough visibility into the debugging process can accelerate development, optimize performance, ensure security, and provide ongoing support for software. This visibility empowers developers to understand, debug, and enhance the intricate interactions between software and hardware, which ultimately leads to better experiences with mobile and other electronic devices.

One factor for providing good debug visibility is providing access to the scandump data of various subsystems within the SoC. Scandump data is a snapshot of the hardware logic at a particular moment in time. This time can be determined, for instance, by the software when it triggers a scandump operation. In a testing facility, this scandump data can be streamed out of the hardware via an on-chip test access port (TAP) interface via a testing bus that is coupled to a debugger attached to the SoC chip. In some cases, the testing bus, specialized testing equipment, and associated testing techniques may comport with a testing standard for circuit boards or integrated circuit (IC) chips. Some testing standards are promulgated by industry organizations, such as the Joint Test Action Group (JTAG). To use the testing bus, however, specialized testing equipment (e.g., a JTAG debugger) is attached to the chip to accept the scandump data that is scanned out serially. Thus, using the testing bus to obtain scandump data is generally feasible only in controlled environments, such as in a testing facility or with a lab setup.

In contrast, when an electronic device is already deployed, a more-feasible mechanism is to stream the scandump data into an available memory device, such as dynamic random-access memory (DRAM) that is part of the device. After a recovery procedure, the scandump data can be transferred from the DRAM to a different storage medium using, e.g., a physical port (e.g., universal serial bus (USB)), a wireless file transfer via Wi-Fi® or Bluetooth®, an email transmission, and so forth. During the scandump procedure in a multiple memory channel environment, the scandump data from each of the SoC subsystems of interest are loaded into the DRAM in an interleaved manner across multiple memory controllers. This involves all memory controllers (e.g., 2, 3, 4, 8, or more memory controllers) of all memory channels being actively operating and functioning correctly to transfer the scandump data into the DRAM portion of each memory channel. If any one of the memory channels encounters a failure, the entire scandump operation also fails.

In an alternative approach, the system can try to retrieve scandump data that is stored once in each memory channel. In this approach, the system stores a quantity of copies of the entire scandump data that is equal to the quantity of memory channels due to the inherent interleaving policy. This involves a failure to utilize, or a wasting of, memory resources that are equal to at least the size of the scandump data multiplied by a quantity that is one fewer than the total of all memory channels. For instance, with four memory channels, three times the reserved memory space is wasted in the system during normal operations. Further, attempts to load the scandump data using a single channel leads to a significant overhead for the software debugger because the debugger must parse and deinterleave the loaded scandump data.

An example scenario with specific memory sizes is described next. Assume, without loss of generality, that the size of the scandump data is 256 megabytes (MB) in a system with four (4) memory channels. The net carveout space across all available channels would therefore be 256 MB to produce a single copy of the scandump data. Considering an interleaving granularity of, e.g., 256 bytes (B), the memory reservation carveout would be 64 MB per memory channel. In such a case, if a crash is encountered due to one of the memory channels—including due to a memory controller thereof, then the entire scandump operation is at risk because all the scandump data is interleaved.

Further, if storing the scandump data relies on using all the memory channels, there is no debug visibility into failures occurring due to a memory controller or another portion of a memory channel in production devices that are in the field and therefore far from testing equipment. Detecting or analyzing failures due to a memory controller requires a lab setup with the SoC connected to a debugger via a JTAG or other testing bus.

To improve software debug visibility, fewer than all memory channels can be used to transfer the scandump data into memory. This leaves the remaining memory channels in the debug domain, thereby improving the debug visibility into memory channel operation. Attempting to load the scandump data using a single memory channel involves a carveout of at least the size of the entire scandump data, which is 256 MB in the above example. Due to the interleaving of a smaller granularity, which is 256 B in the above example, the required memory reservation carveout can only be obtained subject to the following conditions. First, there is a carveout of four contiguous/adjacent memory spaces for all four of the memory channels, which causes an overall carveout of four times (4×) the size of the scandump data. This results in a memory carveout of three times (3×) the size of the scandump data in the DRAM that is unusable by other entities. This lowers the total useable DRAM size or increases the cost of a given amount of useable DRAM. Second, due to the interleaving scheme, when a software debugger is reading back the scandump data from the DRAM, the debugger must retrieve four-times the amount of data, de-interleave the retrieved data, and discard 3× the size of the scandump data (75% of the retrieved data) that is read from the “unused” memory channels. This increases the complexity of the software debugger.

With the approaches described above, a cause of the wasteful memory-overhead amount is due to the presence of a fixed channel-interleaving granularity that is below a size that can contain the scandump data in its entirety. Any data transfer of more than the interleaving granularity (IG) involves multiple memory channels, which consequently reduces the software debugging visibility. If a system instead causes a single memory channel to store a complete copy of the scandump data with the smaller interleaving granularity, the debugging software overhead is significantly increased because the software is responsible for parsing the resultant data in order to identify valid data and discard the noise.

In contrast with the approaches described above, this document describes various implementations that can address the issues described above and/or achieve one or more of the following aspects. First, software debugging visibility into the operations of the memory channels can be increased. This enables testers to debug failures originating from, e.g., a memory controller of a memory channel without a dependency on specialized test equipment. Second, a memory range carved out from the system address space for the scandump data can have a reduced memory-overhead amount.

In example implementations, logic partitions a memory address space that is mapped onto DRAM into at least two regions: a first region and a second region. The system institutes a first interleaving granularity with the first region and a second interleaving granularity with the second region, with the first interleaving granularity different from the second interleaving granularity. The system includes multiple memory channels having a certain quantity (e.g., four). Each region is partitioned into multiple segments that can have the same certain quantity. Accordingly, each respective segment of the multiple segments in each region can correspond to a respective memory channel of the multiple memory channels. The first region can include multiple first-region segments, and the second region can include multiple second-region segments. Thus, the first region can include a first-region segment for each memory channel, and the second region can include a second-region segment for each memory channel.

For example, a first first-region segment can correspond to a first memory channel, and a second first-region segment can correspond to a second memory channel. Similarly, a first second-region segment can correspond to the first memory channel, and a second second-region segment can correspond to the second memory channel. Each segment “inherits” or otherwise has the same interleaving granularity as the region to which it belongs or forms a part. The per-channel region-based segments can have a size that is based on or otherwise corresponds to the region to which it belongs. The first-region segments can be assigned or allocated a size that is sufficient to accommodate the scandump data produced by a scandump operation that is targeting particular circuitry (e.g., one or more SoC subsystems). More specifically, the size of each first-region segment may be set to be the smallest power of two that exceeds the size of the targeted scandump data. This is 256 MB in the example set forth above. The size of the first-region segments may also be the same size as the first interleaving granularity of the first region. The second-region segments can be established to be of any size. By way of example, each second-region segment can be an equal portion of the address space that remains after the first-region segments are allocated memory space—e.g., if the memory address space is partitioned into two regions but not three or more.

After partitioning, the resulting memory address space mapped to the DRAM has first and second regions in which the first region is interleaved with a larger granularity than the second region. This allows the entire scandump data to be routed to a single memory channel without interleaving or additional multi-memory-channel overhead using a first-region segment. In example operations, as part of a scandump operation, logic transfers scandump data to a selected or reserved first-region segment of the first region. Prior to the scandump operation, the other first-region segments can be used to store “regular” data of one or more executing software programs. After a recovery procedure, the stored scandump data can be accessed via a single memory channel without activating other memory channels or performing deinterleaving.

Additionally, because the partitioning policy is equally applicable for regular operations, application software can access the unused first-region segments for non-debugging purposes. Hence, the wastage of DRAM space is appreciably reduced as compared to the approaches described above. Further, described implementations enable a scandump operation to be performed while keeping only a single selected memory channel in a functional mode. This allows the remaining memory channels to be placed in a scan mode, which provides debug visibility into the memory controllers thereof. These and other example implementations and operations are described herein.

### Example Environments and Electronic Devices

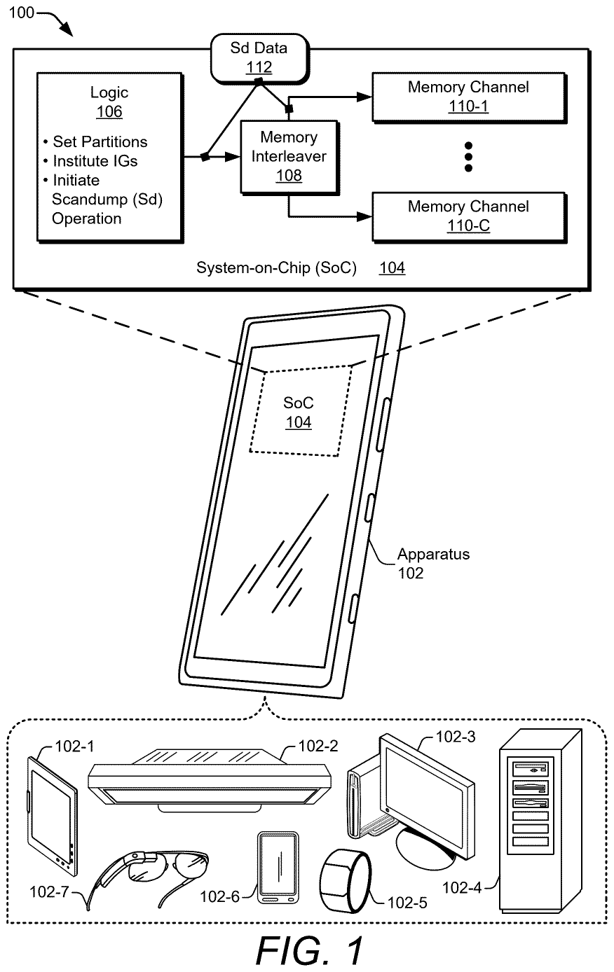

FIG. 1 illustrates, at 100 generally, an example apparatus 102 with logic 106 and multiple memory channels 110 that can implement enhanced memory-channel-focused scandump. As shown, the apparatus 102 includes at least one system-on-chip 104 (SoC 104) or other integrated circuit (IC) chip. In example implementations, the SoC 104 includes at least one instance of logic 106, at least one memory interleaver 108, and multiple memory channels 110-1 . . . 110-C, with “C” representing an integer greater than one. As described herein, the logic 106 can cause scandump data 112 (“Sd Data 112”) to be loaded into fewer than all the multiple memory channels 110-1 . . . 110-C, including into a single memory channel 110 such as a first memory channel 110-1.

In this example, the apparatus 102 is depicted as a smartphone. The apparatus 102 may, however, be implemented as any suitable computing or other electronic device as described herein. Examples of the apparatus 102 include a mobile electronic device or mobile device, mobile communication device, modem, cellular or mobile phone, mobile station, gaming device, navigation device, media or entertainment device (e.g., a media streamer or gaming controller), laptop computer, desktop computer, tablet computer, smart appliance, vehicle-based electronic system, wearable computing device (e.g., clothing, watch, or reality-altering glasses), Internet of Things (IoTs) device, sensor, stock management device, electronic portion of a machine or piece of equipment (e.g., a vehicle or robot), memory storage device (e.g., a solid-state drive (SSD)), server computer or portion thereof (e.g., a server blade or rack or another part of a datacenter), and the like. Illustrated examples of the apparatus 102 include a tablet device 102-1, a smart television 102-2, a desktop computer 102-3, a server computer 102-4, a smartwatch 102-5, a smartphone (or document reader) 102-6, and intelligent glasses 102-7 (e.g., virtual or mixed reality glasses).

Generally, a scandump operation is a type of debugging procedure that produces a copy of the logical state of digital circuitry when the scandump is triggered. In a typical testing environment, the scandump data is read out from an IC chip in a serial manner using specialized testing equipment. Using specialized testing equipment is difficult, however, for electronic devices that are already deployed because most environments lack such equipment. To produce scandump data “in the field” without testing equipment, the scandump data can be stored in a local memory, such as dynamic random-access memory (DRAM), of an electronic device. Production, extraction, or analysis of the scandump data becomes more difficult if the electronic device interleaves stored data across multiple memory channels, such as those depicted in FIG. 1.

With data interleaving, even a block of related data is typically spread across multiple memory channels to increase memory-access bandwidth. This complicates the storing, retrieving, or viability of scandump data. In a first approach absent the techniques described in this document, the scandump data can be stored “once” across the multiple memory channels. With this approach, the failure of one memory channel can be fatal to securing the scandump data. In a second approach that does not utilize the techniques of this document, the scandump data can be stored multiple times across the multiple memory channels. For instance, four copies of the scandump data can be produced across four memory channels using an interleaving mechanism. Four times the size of the scandump data must therefore be reserved in the DRAM for this second approach. Further, although there are multiple copies of the scandump data, no single copy is stored contiguously due to the interleaving. Thus, with both approaches, there is significant overhead to obtain a complete copy of the scandump data during the debugging process. Both approaches also fail to provide a mechanism to perform a scandump operation on a memory channel because all memory channels are being used to store the scandump data for circuitry other than that of the memory channels.

To address these issues and at least partially ameliorate them, this document describes example techniques that enable a complete copy of the scandump data 112 to be stored in a single memory channel (e.g., the first memory channel 110-1) without wasting an equal-sized amount of space in the other memory channels (e.g., the “Cth” memory channel 110-C). Additionally, the stored scandump data 112 is not interleaved, so the debugging—such as data extraction and analysis—is simplified. In example implementations, the logic 106 partitions (e.g., sets partitions of) a logical address space into two regions: a first region and a second region.

The logic 106 can institute interleaving granularities (IGs) in a region-by-region manner based, for instance, on hard-coded instructions that are part of the memory interleaver 108. Thus, each region may have a different interleaving granularity. A first interleaving granularity of the first region is sufficiently large to encompass the scandump data 112 for the targeted circuitry. A second interleaving granularity of the second region can be smaller, and even significantly smaller like a default interleaving granularity. Each region can also be partitioned into multiple segments, with each segment respectively corresponding to a memory channel of multiple memory channels. Segments of the first region, or first-region segments, can be partitioned to be at least as large as the size of the targeted scandump data 112 or the size of the first interleaving granularity.

In example operations, one segment of the first region is reserved for scandump data 112. This one segment is associated with a selected memory channel. The other segments of the first region can be used by software to store into other memory channels. Because of the size of the first interleaving granularity, data stored in the other first-region segments will typically not be interleaved across memory channels. Thus, although this DRAM space is not wasted, the other first-region segments may be used for data that does not have high-bandwidth requirements, such as data that can be relatively static (e.g., boot images, firmware images, and debug images). The segments of the second region can be used to store “normal” data with full interleaving across the multiple channels and with the corresponding higher bandwidth.

When a scandump operation is triggered (e.g., with an initiate scandump (Sd) command), the other memory channels that are not reserved for storing the scandump data 112 can be frozen. The scandump data 112 can then be streamed to the selected memory channel, which can then be frozen, too. After a recovery procedure, a debugging program can retrieve the scandump data 112 from the single selected memory channel. This scandump data 112, due to the size of the first interleaving granularity, can be complete and contiguous, which makes the retrieval and analysis process simpler and faster. Further, a non-selected memory channel can remain free to perform a scandump operation to facilitate debugging the interaction between software and the circuitry of the memory channels. In these manners, described implementations can increase the amount of usable memory during regular program execution while producing a non-interleaved, contiguous instance of scandump data 112. Described implementations also enable the debugging of memory channel usage with a scandump operation.

### Example Apparatuses and Operational Schemes

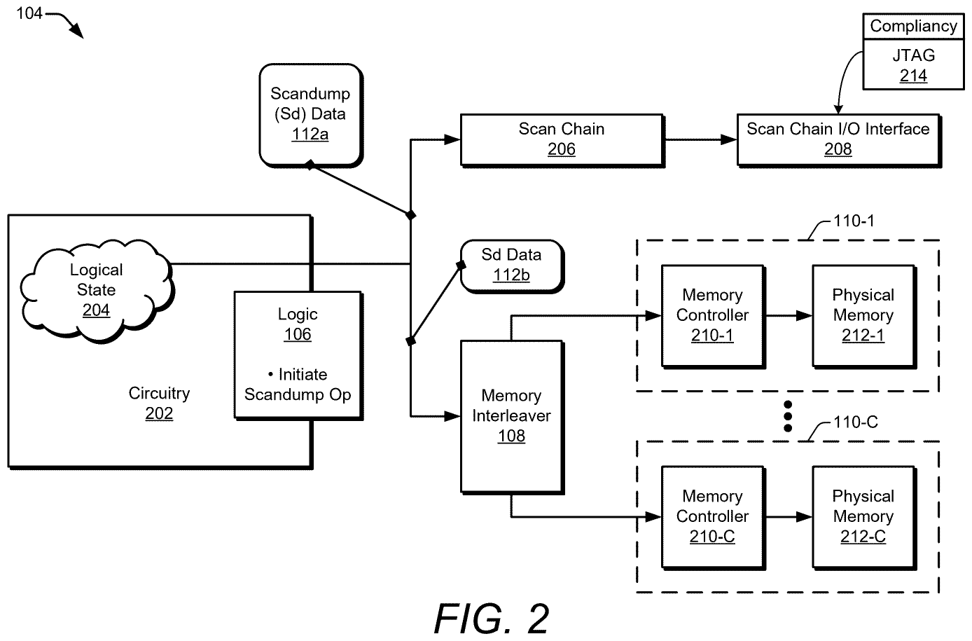

FIG. 2 is an example schematic diagram of an SoC 104 illustrating a memory interleaver 108, circuitry 202 that can realize logic 106, and multiple memory channels 110-1 . . . 110-C that can jointly implement enhanced memory-channel-focused scandump. The circuitry 202 can include or realize a logical state 204 that represents logic values of registers and other digital circuit components as these logic values change over time while software is being executed. As shown, the SoC 104 can also include a scan chain 206 and a scan chain input/output (I/O) interface 208. The scan chain I/O interface 208 may comport with one or more government, industry, or other standards. For example, the scan chain I/O interface 208 may be compliant with at least one JTAG standard 214.

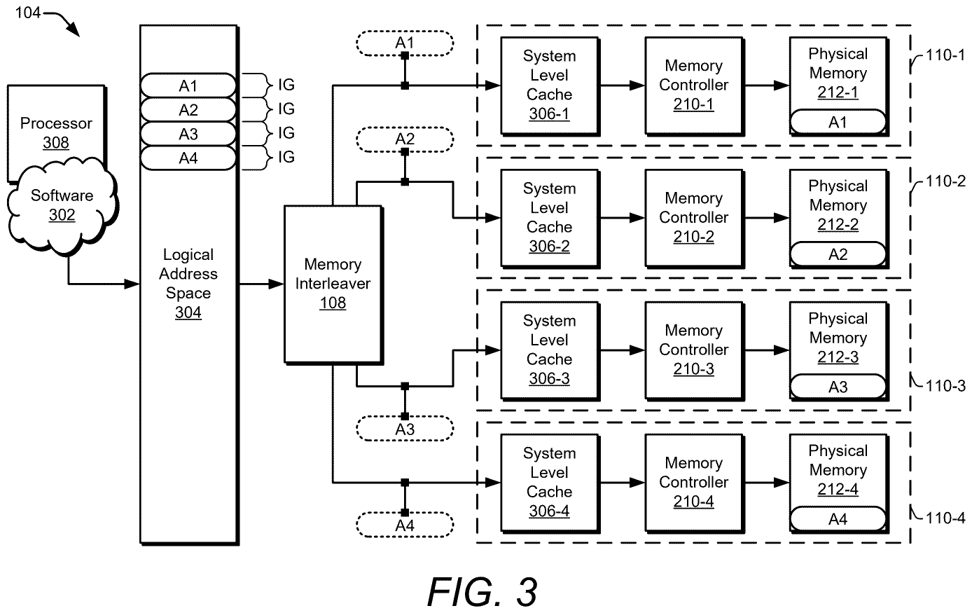

In example implementations, each respective memory channel 110 can include a respective memory controller 210 and a respective instance of physical memory 212, such as at least one DRAM die. For example, a first memory channel 110-1 can include a first memory controller 210-1 and a first physical memory 212-1. A second memory channel 110-2 can include a second memory controller 210-2 and a second physical memory 212-2 (as shown in FIG. 3). A “Cth” memory channel 110-C can include a “Cth” memory controller 210-C and a “Cth” physical memory 212-C. The circuitry 202 or the logic 106 thereof (including both in a permitted, but optional, interpretation of the word “or” as representing an inclusive-or relationship) is coupled to the memory interleaver 108. The memory interleaver 108 is coupled to the multiple memory channels 110-1 . . . 110-C via each memory controller 210 thereof. The memory interleaver 108 is also coupled between the logic 106 and the multiple memory channels 110-1 . . . 110-C. Further, each respective memory controller 210 is coupled to each respective instance of physical memory 212.

Although not shown, the logic 106 can include a debug controller that controls debugging operations, including the production and transferring or storing of the scandump data 112. In example operations, when testing equipment is available, the logic 106 can initiate a scandump operation. The circuitry 202 provides the logical state 204 as the scandump data 112a. The scandump data 112a is advanced along the scan chain 206 to the scan chain I/O interface 208. The JTAG-compliant testing equipment (not shown), which is coupled to the scan chain I/O interface 208, accepts the scandump data 112a that is output from the scan chain I/O interface 208.

At times, however, the SoC 104 and the apparatus 102 (e.g., of FIG. 1) that contains the SoC 104 may be remote from testing equipment, such as after the apparatus 102 is deployed. In example operations, when testing equipment is not available, the logic 106 can still initiate a scandump operation. In response, the circuitry 202 provides the logical state 204 as the scandump data 112b. The logic 106 transfers the scandump data 112b to one or more of the multiple memory channels 110-1 . . . 110-C. This can be effected in any of numerous ways. For example, the scan chain 206, or a fully or partially separate scan chain, can propagate the scandump data 112b from the circuitry 202 to the memory interleaver 108. Additionally or alternatively, the logic 106 (e.g., a debug controller thereof) can indicate that the scandump data 112b is associated with an address range that maps to the region and segment that is reserved for the scandump data 112b. Accordingly, the memory interleaver 108 routes such data to the intended memory channel 110. Example functionality of the memory interleaver 108, including with respect to storing scandump data 112b using the multiple memory channels 110-1 . . . 110-C, is described below with reference to FIGS. 3-6.

FIG. 3 is an example schematic diagram of an SoC 104 illustrating memory interleaving across multiple memory channels 110-1 to 110-4 (e.g., “C” equals four (4) in these examples) in accordance with enhanced memory-channel-focused scandump. As shown, the SoC 104 also includes at least one processor 308. In addition to a memory controller 210 and physical memory 212, each respective memory channel 110 of the multiple memory channels 110-1 to 110-4 can include a respective system level cache 306. Thus, the first memory channel 110-1 can include the first memory controller 210-1, the first physical memory 212-1, and a first system level cache 306-1. The second memory channel 110-2 can include the second memory controller 210-2, the second physical memory 212-2, and a second system level cache 306-2. The third memory channel 110-3 can include a third memory controller 210-3, a third physical memory 212-3, and a third system level cache 306-3.

With “C” equal to four, the fourth memory channel 110-4 can include a fourth memory controller 210-4, a fourth physical memory 212-4, and a fourth system level cache 306-4. In some cases, the memory interleaver 108 is coupled to the multiple memory channels 110-1 to 110-4 via each system level cache 306 thereof. Each system level cache 306 is coupled to each memory controller 210, and each memory controller 210 is coupled to each instance of physical memory 212. The memory controller 210 may be coupled between the system level cache 306 and the physical memory 212. The memory interleaver 108 may be part of, or operate in conjunction with, an address mapper, hashing fabric that parses addresses received from the software 302, and so forth.

In example operations, the software 302 executes on the processor 308. The software 302 can include a basic input/output system (BIOS), an operating system (OS), one or more applications or other programs, and so forth. The software 302 operates with or instantiates a logical address space 304. The logical address space 304 (or memory address space) is mapped onto the multiple instances of physical memory 212-1 to 212-4. Consider, for example, a scenario in which four data portions A1, A2, A3, and A4, which are part of a related block of data, are present in the logical address space 304. Each data portion is of an interleaving granularity (IG) size.

Thus, in some cases, the memory interleaver 108 can implement the one or more interleaving granularities (IGs) at a hardware level. With data interleaving, the memory interleaver 108 stores the data portion A1 in the first physical memory 212-1 via the first system level cache 306-1 and using the first memory controller 210-1. The memory interleaver 108 stores the data portion A2 in the second physical memory 212-2 via the second system level cache 306-2 and using the second memory controller 210-2. The memory interleaver 108 stores the data portion A3 in the third physical memory 212-3 via the third system level cache 306-3 and using the third memory controller 210-3. The memory interleaver 108 stores the data portion A4 in the fourth physical memory 212-4 via the fourth system level cache 306-4 and using the fourth memory controller 210-4.

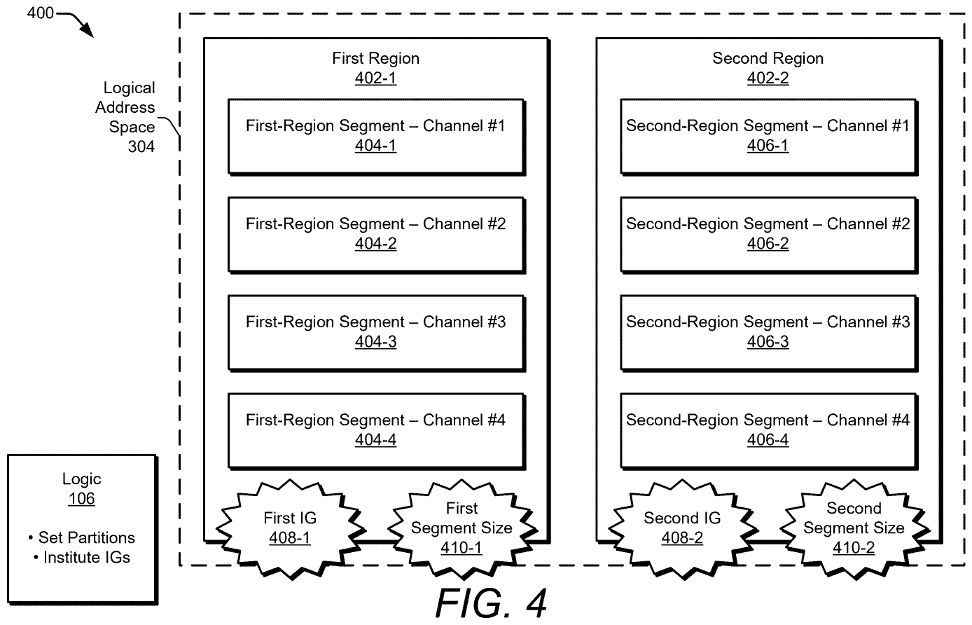

FIG. 4 is a schematic diagram 400 illustrating example approaches to partitioning a logical address space 304 into multiple regions 402 and multiple segments 404 and 406, with the partitioning involving multiple interleaving granularities 408 in accordance with enhanced memory-channel-focused scandump. For the description of FIG. 4 to match the description of FIG. 3 (where “C” equals four), each region 402 is separated into four segments, by way of example only. This example aligns the quantity of segments per region with the example quantity of four memory channels 110-1 to 110-4.

In example implementations, the logic 106 sets partitions and can institute interleaving granularities in conjunction with the interleaving hardware. For example, the logic 106 can partition the logical address space 304 into multiple regions, such as a first region 402-2 and a second region 402-2. The logic 106 can partition the individual regions 402 into multiple segments, which may be based on a quantity of memory channels. For example, the first region 402-1 can be partitioned into four first-region segments 404: a first first-region segment 404-1 (“first-region segment—channel #1”), a second first-region segment 404-2 (“first-region segment—channel #2”), a third first-region segment 404-3 (“first-region segment—channel #3”), and a fourth first-region segment 404-4 (“first-region segment—channel #4”).

Further, the second region 402-2 can be partitioned into four second-region segments 406: a first second-region segment 406-1 (“second-region segment—channel #1”), a second second-region segment 406-2 (“second-region segment—channel #2”), a third second-region segment 406-3 (“second-region segment—channel #3”), and a fourth second-region segment 406-4 (“second-region segment—channel #4”). Although the logical address space 304 is partitioned into two regions 402-1 and 402-2, the logical address space 304 can instead be partitioned into more than two regions. Also, although each region 402 is partitioned into four segments 404 or 406, each region may alternatively be partitioned into more or fewer segments, and each region 402 may have a different quantity of segments. Additionally, the quantity of segments 404 or 406 per region 402 may differ from the quantity of multiple memory channels 110-1 . . . 110-C that are present in the memory subsystem.

The logic 106 also establishes the first interleaving granularity 408-1 (“first IG”) for the first region 402-1 and the second interleaving granularity 408-2 (“second IG”) for the second region 402-2. The establishment of these interleaving granularities can be performed in conjunction with hardware constraints or other parameters. For example, one or more hashing algorithms that are built into (or flash-able into) the hardware can be used to establish at least one interleaving granularity. As part of the partitioning of each region 402 into multiple segments, the logic 106 can establish a size for each segment. In some cases, each segment of a given region has a same size. However, different segments of a same region 402 may instead have different sizes.

As shown in FIG. 4, each first-region segment 404 has a first segment size 410-1, and each second-region segment 406 has a second segment size 410-2. Assuming a first-region segment 404 of the first region 402-1 is to store the scandump data, the first segment size 410-1 can be based on a size of the scandump data to be stored within the first-region segment 404. For example, the first segment size 410-1 can be larger than the scandump data, such as a memory size corresponding to the next power of two that is larger than the scandump data. In some cases, the first segment size 410-1 can be equal to (“=”), or equal to or larger than (“>=”), a size of the first interleaving granularity 408-1. In at least some of such cases, the second region 402-2 can store normal data for application software or other non-scandump data. If there are two regions—and not more than two regions, then each second-region segment 406 can have a size equal to one-fourth of the logical address space 304 that remains after the partitioning for the first region 402-1.

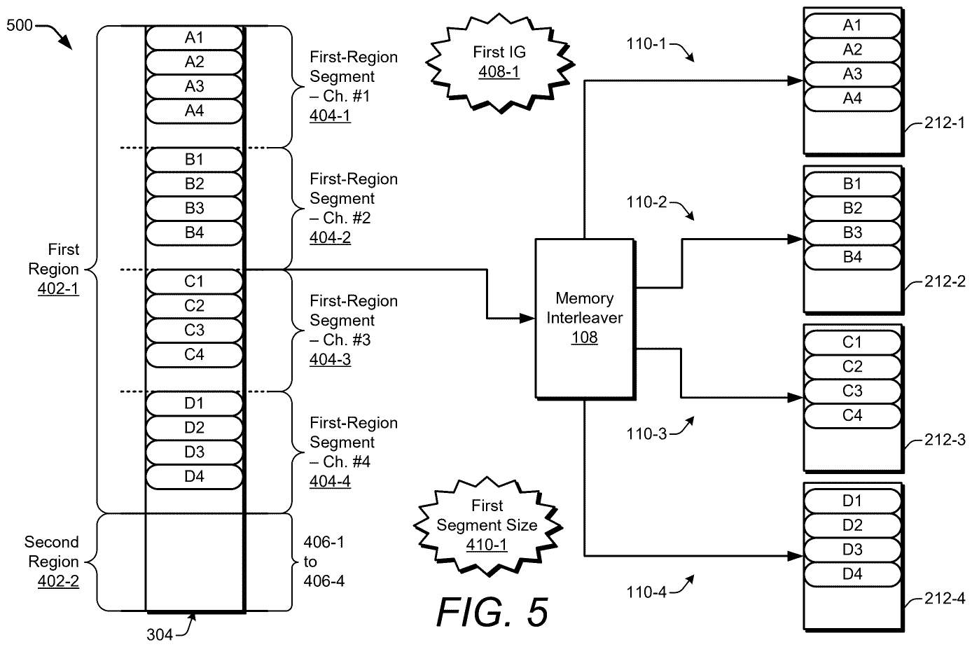

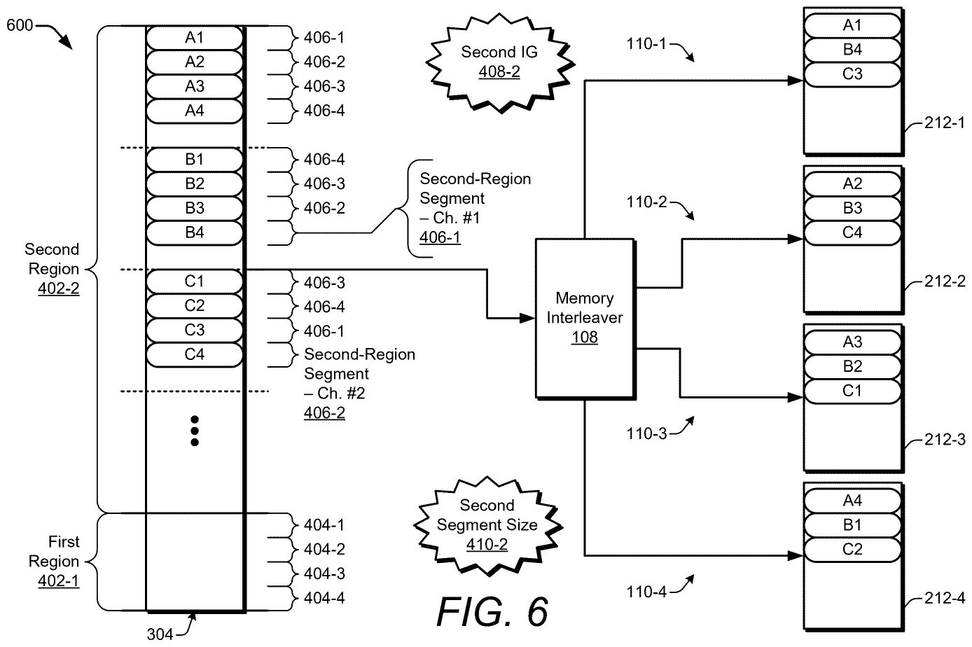

FIG. 5 is an example schematic diagram 500 illustrating memory interleaving across multiple memory channels 110-1 to 110-4 with respect to a first region 402-1 having a first interleaving granularity (IG) 408-1 in accordance with enhanced memory-channel-focused scandump. The logical address space 304 is separated into the first region 402-1 and the second region 402-2. Storing data of the second region 402-2, which includes multiple segments 406-1 to 406-4, in the multiple physical memories 212-1 to 212-4 of the multiple memory channels 110-1 to 110-4 is described below with reference to FIG. 6. In FIG. 5, each first-region segment 404 is depicted as having at least four data portions. For example, the first first-region segment 404-1 includes the data portions A1, A2, A3, and A4, and the second first-region segment 404-2 includes the data portions B1, B2, B3, and B4. Further, the third first-region segment 404-3 includes the data portions C1, C2, C3, and C4, and the fourth first-region segment 404-4 includes the data portions D1, D2, D3, and D4.

In example implementations, each first-region segment 404 has a first segment size 410-1 that is equal to the first interleaving granularity 408-1. However, the first segment size 410-1 can differ from the first interleaving granularity 408-1. The memory interleaver 108 routes and stores each (up to all) of the data portions A1-A4 in the same memory channel 110, which is the first memory channel 110-1 in FIG. 5. Thus, the first physical memory 212-1 stores the data portions A1-A4 because the first interleaving granularity 408-1 is sufficiently large that the memory interleaver 108 does not switch to a different memory channel 110 before each of the data portions A # of the first first-region segment 404-1 are stored in the first memory channel 110-1. Thus, if the scandump data is concentrated in, or assigned to the address range of, the first first-region segment 404-1, the entirety of the scandump data is routed to and stored in a single memory channel, which is the first memory channel 110-1 in FIG. 5.

Similarly, the memory interleaver 108 routes and stores each (up to all) of the data portions B1-B4 of the second first-region segment 404-2 in the second physical memory 212-2 of the second memory channel 110-2. The memory interleaver 108 routes and stores each (up to all) of the data portions C1-C4 of the third first-region segment 404-3 in the third physical memory 212-3 of the third memory channel 110-3. Also, the memory interleaver 108 routes and stores each (up to all) of the data portions D1-D4 of the fourth first-region segment 404-4 in the fourth physical memory 212-4 of the fourth memory channel 110-4. Excluding the first first-region segment 404-1, which is reserved for scandump data, the other first-region segments 404-2 to 404-4 can store other, non-scandump data during regular operations. As noted herein, data stored in the first-region 402-1 experiences a lower memory bandwidth due to the absence of memory-channel interleaving, so the contents of this data may be selected accordingly.

FIG. 6 is an example schematic diagram 600 illustrating memory interleaving across multiple memory channels 110-1 to 110-4 with respect to a second region 402-2 having a second interleaving granularity 408-2 in accordance with enhanced memory-channel-focused scandump. The logical address space 304 is separated into the first region 402-1 and the second region 402-2. Storing data of the first region 402-1, which includes multiple segments 404-1 to 404-4, in the multiple physical memories 212-1 to 212-4 of the multiple memory channels 110-1 to 110-4 is described above with reference to FIG. 5. Although described separately across FIGS. 5 and 6, the storing of data of the first region 402-1 and the second region 402-2 can occur in a temporally overlapping fashion while the software 302 executes on the processor 308 (both of FIG. 3). Additionally, although the interleaving is described in terms of storing data to the multiple physical memories 212-1 to 212-4 of the multiple memory channels 110-1 to 110-4, the principles are applicable to retrieving data and thus to accessing data (e.g., reading or writing data) generally.

In FIG. 6, each second-region segment 406 is depicted as having at least three data portions. For example, the first second-region segment 406-1 includes the data portions A1, B4, and C3. The second second-region segment 406-2 includes the data portions A2, B3, and C4. Further, the third second-region segment 406-3 includes the data portions A3, B2, and C1. The fourth second-region segment 406-4 includes the data portions A4, B1, and C2.

In example implementations, each second-region segment 406 has multiple data portions A #, B #, C #, and so forth. For clarity, the size of each data portion is equal to the second interleaving granularity 408-2. The second segment size 410-2 of each second-region segment 406 is therefore greater than not only the size of each data portion but also the size of the second interleaving granularity 408-2. In some cases, the second segment size 410-2 can be one-fourth of the size of the total logical address space 304 that is not consumed by four times the first segment size 410-1. In other words, once the carveout size for the scandump data 112 has been determined and used to establish the first segment size 410-1 for the multiple first-region segments 404, the remaining memory space can be assigned to the multiple second-region segments 406 (in situations with no third region).

In example operations, the memory interleaver 108 routes and stores each data portion in one of the memory channels 110-1 to 110-4 in accordance with the address mapping and interleaving policies that have been established. This routing includes accounting for the respective correspondences between second-region segments 406-1 to 406-4 and memory channels 110-1 to 110-4—e.g., based on the hashing of the addresses of the data portions in the second-region segments 406. Thus, the memory interleaver 108 routes the data portions A1, B4, and C3 of the first second-region segment 406-1 to the first memory channel 110-1 for storing in the first physical memory 212-1. The memory interleaver 108 routes the data portions A2, B3, and C4 of the second second-region segment 406-2 to the second memory channel 110-2 for storing in the second physical memory 212-2. The memory interleaver 108 routes the data portions A3, B2, and C1 of the third second-region segment 406-3 to the third memory channel 110-3 for storing in the third physical memory 212-3. The memory interleaver 108 also routes the data portions A4, B1, and C2 of the fourth second-region segment 406-4 to the fourth memory channel 110-4 for storing in the fourth physical memory 212-4.

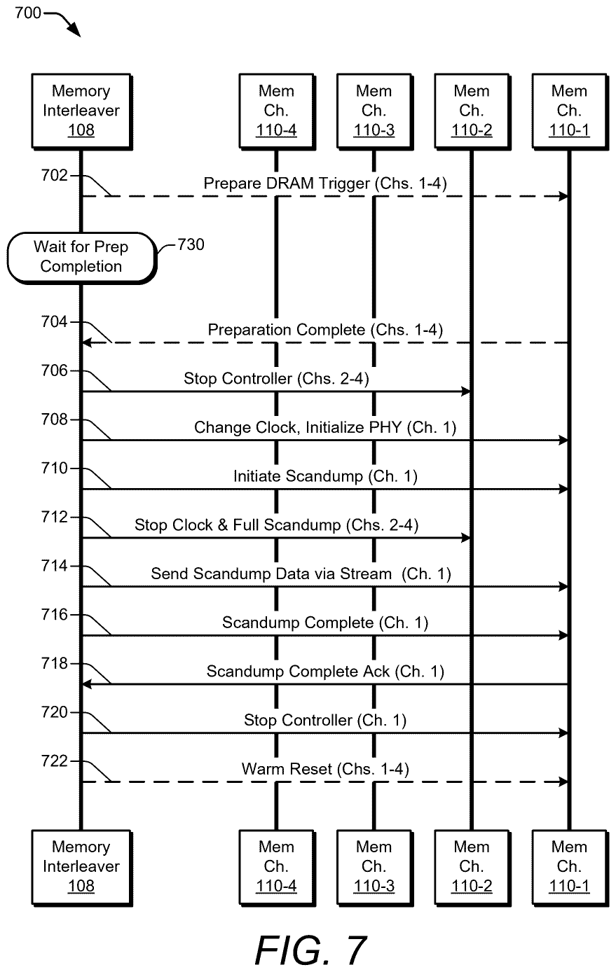

FIG. 7 is an example sequence diagram 700 for performing a scandump operation that is focused on at least one memory channel 110 of multiple memory channels 110-1 to 110-4 in accordance with enhanced memory-channel-focused scandump. The sequence diagram 700 includes a memory interleaver 108 and four memory channels 110-1 to 110-4. The principles, however, are applicable to memory systems with more or fewer memory channels. The sequence diagram 700 includes eleven (11) commands 702-722 (or other signaling) that are transmitted between the memory interleaver 108 and one or more memory channels. Each command may be signaled with respect to, for example, one memory channel (e.g., the first memory channel 110-1), three memory channels (e.g., the second to fourth memory channels 110-2 to 110-4), or four memory channels (e.g., the first to fourth memory channels 110-1 to 110-4). The destination(s) or origin(s) for each command are indicated parenthetically in FIG. 7.

In example implementations, the sequence diagram 700 relates to a scandump operation in which scandump data for the logical state of circuitry is scanned into a local memory, specifically via a single memory channel 110. This single-channel transfer of the scandump data is facilitated by an interleaving policy in which the entirety of the scandump data is routed to a single memory channel 110, which is the first memory channel 110-1 in the example of FIG. 7.

For command 702, the memory interleaver 108 transmits to the four memory channels a trigger to prepare the DRAM for the scandump operation. At 730, the memory interleaver 108 then waits for the DRAM preparation to be complete. For command or signaling 704, each memory channel transmits to the memory interleaver 108 a confirmation that the preparation has been completed. At command 706, the memory interleaver 108 instructs the second to fourth memory channels 110-2 to 110-4 to stop the operations of each respective memory controller.

For command 708, the memory interleaver 108 commands the first memory channel 110-1 to change its clock and initialize the physical layer (PHY) of the bus to receive the scandump data. At command 710, the memory interleaver 108 instructs the first memory channel 110-1 to initiate the scandump operation for the first memory channel 110-1 to receive the scandump data from the corresponding circuitry. For command 712, the memory interleaver 108 instructs the second to fourth memory channels 110-2 to 110-4 to stop operating in accordance with the clock and to perform a full scandump operation. In other words, any of the second to fourth memory channels 110-2 to 110-4 can implement a scandump operation to provide information on their logical state to a debugger. By taking these three memory controllers out of the regular operational mode, the circuitry of the memory controllers can be debugged. At command 714, the memory interleaver 108 sends the scandump data from the general circuitry via a stream (optionally via a scan chain) to the first memory channel 110-1. A debugger controller (not shown) can cause the scandump data to be associated with the memory address range corresponding to the first first-region segment 404-1 that is routed to the first memory channel 110-1 in accordance with the policies instituted for mapping addresses and for memory interleaving (e.g., the first interleaving granularity 408-1).

At command 716, the memory interleaver 108 indicates to the first memory channel 110-1 that the scandump transfer is complete. At signaling 718, the first memory channel 110-1 acknowledges that the scandump data has been received and stored and that the scandump operation has been completed. For command 720, the memory interleaver 108 instructs the first memory channel 110-1 to stop its memory controller. At command 722, the memory interleaver 108 causes the four memory controllers 110-1 to 110-4 to perform a warm reset—e.g., as part of a recovery procedure. This can enable the scandump data that is stored in the first memory channel 110-1 to be retrieved for analysis.

Having generally described schemes, techniques, and hardware for implementing enhanced memory-channel-focused scandump, this discussion now turns to example methods.

### Example Methods

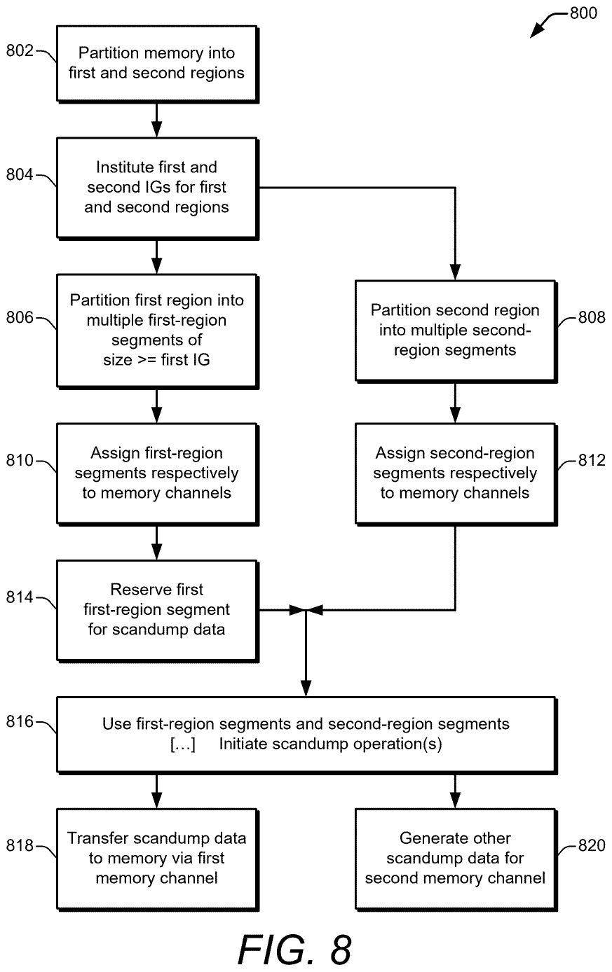

FIG. 8 is a flow chart 800 illustrating an example process for enhanced memory-channel-focused scandump. The flow chart 800 includes ten (10) blocks 802 and 820. In example implementations, the operations of the flow chart 800 may be performed by the logic 106, the memory interleaver 108, at least one memory controller 210, and so forth. At 802, a memory address space is partitioned into a first region 402-1 and a second region 402-2. The partitioning may be performed, for instance, by the operating system (e.g., by the kernel thereof). At 804, a first interleaving granularity 408-1 is instituted for the first region 402-1, and a second interleaving granularity 408-2 is instituted for the second region 402-2. The institution of the first and second interleaving granularities 408-1 and 408-2 may be accomplished in conjunction with hardware settings of a hashing algorithm of the memory interleaver 108.

At 806, the first region 402-1 is partitioned into multiple first-region segments 404 with each first-region segment 404 having a first segment size 410-1 that is greater than or equal to the size of the first interleaving granularity 408-1. At 808, the second region 402-2 is partitioned into multiple second-region segments 406. At 810, the multiple first-region segments 404 are respectively assigned to multiple memory channels 110. At 812, the multiple second-region segments 406 are also respectively assigned to the multiple memory channels 110.

At 814, the first first-region segment 404-1 is reserved for storing scandump data for targeted circuitry 202 via a first memory channel 110-1. The other first-region segments 404 can be used by software for storing general, non-scandump data, including data without high-bandwidth demands. At 816, executing software can use the second-region segments 406 to store “regular” data, such as non-scandump data and data that benefits from the higher memory-accessing bandwidth achieved with memory interleaving at a lower interleaving granularity. The executing software can also use the other first-region segments 404, besides the first first-region segment 404-1, for non-scandump data for which lower memory-accessing bandwidth is acceptable. At some point, software or hardware initiates one or more scandump operations. The triggering of a scandump operation can be based on software execution or a debugging protocol or can be responsive to detection of an error.

The initiated scandump operation can produce general scandump data from core circuitry 202. At 818, the general scandump data is transferred to memory (e.g., the first physical memory 212-1) via the first memory channel 110-1 in accordance with the assignment of the first first-region segment 404-1 to the first memory channel 110-1 and the reservation of the first first-region segment 404-1 for the scandump data. At 820, the second memory channel 110-2 can generate other scandump data representative of the logical state of the second memory channel 110-2. This other scandump data can also be stored locally in memory (e.g., via the first memory channel 110-1 or the third memory channel 110-3) for subsequent extraction or scanned out via an interface for debugging. Other scandump data can also be generated for any memory channel that is not reserved for loading scandump data.

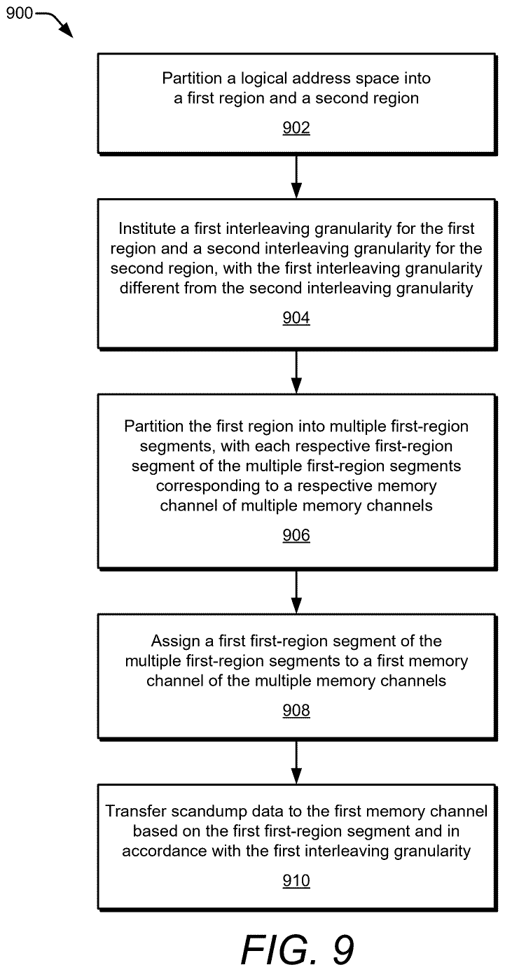

FIG. 9 is a flow diagram 900 illustrating an example process for enhanced memory-channel-focused scandump. The flow diagram 900 includes five (5) blocks 902-910. In example implementations, the operations of the flow diagram 900 may be performed by an SoC 104, such as the logic 106, the memory interleaver 108, at least one memory controller 210, and so forth.

At block 902, a logical address space is partitioned into a first region and a second region. For example, the logic 106 can partition a logical address space 304 into a first region 402-1 and a second region 402-2. To do so, a kernel portion of an operating system may partition the logical address space 304 into multiple regions 402-1 to 402-2 to utilize different interleaving granularities. The first region 402-1 may be secure requiring privileged access.

At block 904, a first interleaving granularity is instituted for the first region, and a second interleaving granularity is instituted for the second region, with the first interleaving granularity different from the second interleaving granularity. For example, the logic 106 in conjunction with the memory interleaver 108 can institute a first interleaving granularity 408-1 for the first region 402-1 and a second interleaving granularity 408-2 for the second region 402-2, with the first interleaving granularity 408-1 different from the second interleaving granularity 408-2. In some cases, the logic 106 may assign address ranges to regions such that a hardware-based interleaving granularity implemented by the memory interleaver 108 will be applied to an intended set of data (e.g., scandump data).

At block 906, the first region is partitioned into multiple first-region segments, with each respective first-region segment of the multiple first-region segments corresponding to a respective memory channel of multiple memory channels. For example, the operating system executing on the logic 106 can partition the first region 402-1 into multiple first-region segments 404. Here, each respective first-region segment 404 of the multiple first-region segments 404 corresponds to a respective memory channel 110 of multiple memory channels 110. A first segment size 410-1 of each of the multiple first-region segments 404 may, for instance, be established based on a size of the first interleaving granularity 408-1 or a size of the targeted scandump data.

At block 908, a first first-region segment of the multiple first-region segments is assigned to a first memory channel of the multiple memory channels. For example, the logic 106 in conjunction with the memory interleaver 108 can assign a first first-region segment 404-1 of the multiple first-region segments 404 to a first memory channel 110-1 of the multiple memory channels 110. In some cases, the assignment may arise from the memory-address hashing algorithm used by the memory interleaver 108 in conjunction with the address range allocated to the first first-region segment 404-1.

At block 910, scandump data is transferred to the first memory channel based on the first first-region segment and in accordance with the first interleaving granularity. For example, the memory interleaver 108 can transfer scandump data 112 to the first memory channel 110-1 based on the first first-region segment 404-1 and in accordance with the first interleaving granularity 408-1. To do so, the memory interleaver 108 may route data having memory addresses that fall within the first first-region segment 404-1 to the same first memory channel 110-1 based on a hashing algorithm that employs the first interleaving granularity 408-1 to those addresses such that the scandump data 112 is not interleaved across multiple memory controllers 210.

In some implementations of a process in accordance with the flow diagram 900, data is stored in the multiple memory channels using the second region and in accordance with the second interleaving granularity. For example, the memory interleaver 108 can store data in the multiple memory channels 110 using the second region 402-2 and in accordance with the second interleaving granularity 408-2. For instance, the memory interleaver 108 may store data (e.g., data portions A #, B #, or C #) into the multiple memory channels 110-1 to 110-4 (e.g., where “C” is equal to four) in accordance with the second interleaving granularity 408-2, which is smaller than the first interleaving granularity 408-1, based on multiple second-region segments 406 (e.g., as shown in FIG. 6).

Aspects of these methods may be implemented in, for example, hardware (e.g., fixed logic circuitry, a controller, a finite state machine, or a processor in conjunction with a memory), firmware, software, or some combination thereof. The methods may be realized to produce one or more of the apparatuses or components shown in FIGS. 1 to 7 and 10, which components may be further divided, combined, and so on. The devices and components of these figures generally represent hardware, such as electronic devices, PCBs, packaged modules, IC chips, components, or circuits; firmware; software; or a combination thereof. Thus, these figures illustrate some of the many possible systems or apparatuses capable of being produced using the described methods.

For the methods described herein and the associated flow chart(s) and/or flow diagram(s), the orders in which operations are shown and/or described are not intended to be construed as a limitation. Instead, any number or combination of the described method operations can be combined in any order to implement a given method or an alternative method, including by combining operations from different ones of the flow chart(s) and flow diagram(s) and the earlier-described schemes and techniques into one or more methods. Operations may also be omitted from or added to the described methods. Further, described operations can be implemented in fully or partially overlapping manners.

### Additional Example Apparatuses and Electronic Devices

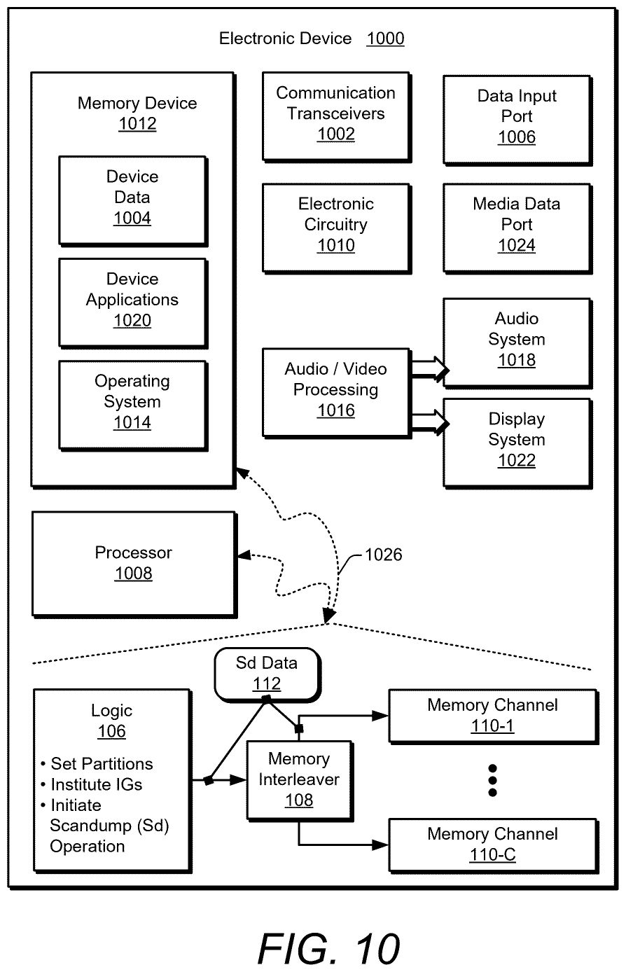

FIG. 10 illustrates various components of an example electronic device 1000 that can implement enhanced memory-channel-focused scandump in accordance with one or more described aspects. The electronic device 1000 may be implemented as any one or combination of a fixed, mobile, stand-alone, or embedded device or in any form of a consumer, computer, portable, user, server, communication, phone, navigation, gaming, audio, camera, messaging, media playback, and/or other type of electronic device 1000, such as the smartphone that is depicted in FIG. 1 as the apparatus 102. One or more of the illustrated components may be realized as discrete components or as integrated components on at least one integrated circuit of the electronic device 1000 or separately or jointly in one or more packages of the electronic device 1000.

The electronic device 1000 can include one or more communication transceivers 1002 that enable wired and/or wireless communication of device data 1004, such as received data, transmitted data, or other information identified above. Example communication transceivers 1002 include near-field communication (NFC) transceivers, wireless personal area network (PAN) (WPAN) radios compliant with various IEEE 802.15 (Bluetooth®) standards, wireless local area network (LAN) (WLAN) radios compliant with any of the various IEEE 802.11 (Wi-Fi®) standards, wireless wide area network (WAN) (WWAN) radios (e.g., those that are 3GPP-compliant) for cellular telephony, wireless metropolitan area network (MAN) (WMAN) radios compliant with various IEEE 802.16 (WiMAX™) standards, infrared (IR) transceivers compliant with an Infrared Data Association (IrDA) protocol, and wired local area network (LAN) (WLAN) Ethernet transceivers.

The electronic device 1000 may also include one or more data input ports 1006 via which any type of data, media content, and/or other inputs can be received, such as user-selectable inputs, messages, applications, music, television content, recorded video content, and any other type of audio, video, and/or image data received from any content and/or data source, including a sensor like a microphone or a camera. The data input ports 1006 may include USB ports, coaxial cable ports, fiber optic ports for optical fiber interconnects or cabling, and other serial or parallel connectors (including internal connectors) for flash memory, DVDs, CDs, and the like. These data input ports 1006 may be used to couple the electronic device to components, peripherals, or accessories such as keyboards, microphones, cameras, or other sensors.

The electronic device 1000 of this example includes at least one processor 1008 (e.g., any one or more of application processors, microprocessors, digital-signal processors (DSPs), controllers, and the like), which can include a combined processor and memory system (e.g., implemented as part of an SoC), that processes (e.g., executes) computer-executable instructions to control operation of the device. The processor 1008 may be implemented as an application processor, embedded controller, microcontroller, security processor, artificial intelligence (AI) accelerator, and the like. Generally, a processor or processing system may be implemented at least partially in hardware, which can include components of an integrated circuit or on-chip system, a digital signal processor (DSP), an application-specific integrated circuit (ASIC), a field programmable gate array (FPGA), a complex programmable logic device (CPLD), and other implementations in silicon and/or other materials.

Alternatively or additionally, the electronic device 1000 can be implemented with any one or combination of electronic circuitry, which may include software, hardware, firmware, or fixed logic circuitry that is implemented in connection with processing and control circuits, which are generally indicated at 1010 (as electronic circuitry 1010). This electronic circuitry 1010 can implement executable or hardware-based modules (not shown in FIG. 10), such as through processing/computer-executable instructions stored on computer-readable media, through logic circuitry and/or hardware (e.g., such as an FPGA), and so forth.

The electronic device 1000 can include a system bus, interconnect, crossbar, data transfer system, switch fabric, or other communication fabric that couples the various components within the device. A system bus or interconnect can include any one or a combination of different bus structures, such as a memory bus or memory controller, a peripheral bus, a universal serial bus (USB), and/or a processor or local bus that utilizes any of a variety of bus architectures.

The electronic device 1000 also includes one or more memory devices 1012 that enable data storage, examples of which include random-access memory (RAM), non-volatile memory (e.g., read-only memory (ROM), flash memory, EPROM, and EEPROM), and a disk storage device. Thus, the memory device(s) 1012 can be distributed across different logical storage levels of a system as well as at different physical components. The memory device(s) 1012 provide data storage mechanisms to store the device data 1004, other types of code and/or data, and various device applications 1020 (e.g., software applications or programs). For example, an operating system 1014 can be maintained as software instructions within the memory device 1012 and executed by the processor 1008.

In some implementations, the electronic device 1000 also includes an audio and/or video processing system 1016 that processes audio and/or video data and/or that passes through the audio and/or video data to an audio system 1018 and/or to a display system 1022 (e.g., a video buffer or a screen of a smartphone or camera). The audio system 1018 and/or the display system 1022 may include any devices that process, display, and/or otherwise render audio, video, display, and/or image data. Display data and audio signals can be communicated to an audio component and/or to a display component via an RF (radio-frequency) link, an S-video link, an HDMI (high-definition multimedia interface) link, a composite video link, a component video link, a DVI (digital video interface) link, an analog audio connection, a video bus, or another similar communication link, such as a media data port 1024. In some implementations, the audio system 1018 and/or the display system 1022 are external or separate components of the electronic device 1000. Alternatively, the display system 1022, for example, can be an integrated component of the example electronic device 1000, such as part of an integrated touch interface.

The electronic device 1000 of FIG. 10 illustrates example implementations of the apparatus 102 of FIG. 1, of an apparatus that includes logic 106 and a memory interleaver 108 to perform enhanced memory-channel-focused scandump as with any of the FIGS. 2 to 9, or some combination thereof. Accordingly, one of the components illustrated in FIG. 10 and discussed above may realize or incorporate at least part of the other components depicted in FIG. 10. These other components include the logic 106, the memory interleaver 108, and the multiple memory channels 110-1 . . . 110-C, in conjunction with the scandump data 112. For example, as indicated by the arrows 1026, the processor 1008 may realize at least part of the logic 106. Further, the memory device 1012 may realize another part of the logic 106, at least a portion of the memory interleaver 108, and at least part of each memory channel 110, such as the physical memory 212 thereof (e.g., of FIGS. 2 and 3).

### Example Aspects and Implementations for Enhanced Memory-Channel-Focused Scandump

In the following, some examples, example aspects, and implementations are described:

Example 1: A method for implementing a scandump operation using at least one memory channel, the method comprising: partitioning a logical address space into a first region and a second region; instituting a first interleaving granularity for the first region and a second interleaving granularity for the second region, the first interleaving granularity different from the second interleaving granularity; partitioning the first region into multiple first-region segments, each respective first-region segment of the multiple first-region segments corresponding to a respective memory channel of multiple memory channels; assigning a first first-region segment of the multiple first-region segments to a first memory channel of the multiple memory channels; and transferring scandump data to the first memory channel based on the first first-region segment and in accordance with the first interleaving granularity.

Example 2: The method of example 1, or any one or more of the examples described herein, wherein: the first interleaving granularity is larger than the second interleaving granularity.

Example 3: The method of example 2, or any one or more of the examples described herein, wherein: the first interleaving granularity is at least three orders of magnitude larger than the second interleaving granularity.

Example 4: The method of example 2, or any one or more of the examples described herein, wherein: the first interleaving granularity is larger than a size of the scandump data transferred to the first memory channel.

Example 5: The method of example 4, or any one or more of the examples described herein, wherein: the scandump data comprises a logical state of targeted circuitry.

Example 6: The method of example 1, or any one or more of the examples described herein, further comprising: storing data in the multiple memory channels using the second region and in accordance with the second interleaving granularity.

Example 7: The method of example 6, or any one or more of the examples described herein, further comprising: partitioning the second region into multiple second-region segments, each respective second-region segment of the multiple second-region segments corresponding to a respective memory channel of the multiple memory channels.

Example 8: The method of example 7, or any one or more of the examples described herein, wherein the storing data comprises: storing the data in the multiple memory channels using the multiple second-region segments and in accordance with the second interleaving granularity.

Example 9: The method of example 8, or any one or more of the examples described herein, wherein the storing the data comprises: interleaving a block of related data across the multiple memory channels using the multiple second-region segments.

Example 10: The method of example 1, or any one or more of the examples described herein, further comprising: partitioning the second region into multiple second-region segments, each respective second-region segment of the multiple second-region segments corresponding to a respective memory channel of the multiple memory channels; storing each first block of related data in its entirety within a single first-region segment of the multiple first-region segments based on each first block of related data being smaller than the first interleaving granularity; and storing each second block of related data across at least two second-region segments of the multiple second-region segments in an interleaved manner based on each second block of related data being larger than the second interleaving granularity.

Example 11: The method of example 1, or any one or more of the examples described herein, further comprising: outputting the scandump data from the first memory channel after a recovery procedure has been performed.

Example 12: The method of example 1, or any one or more of the examples described herein, further comprising: generating other scandump data that corresponds to a logical state of a second memory channel of the multiple memory channels; and transferring the other scandump data to at least one memory using a memory channel of the multiple memory channels, the memory channel excluding the second memory channel.

Example 13: The method of example 1, or any one or more of the examples described herein, further comprising: assigning a second first-region segment of the multiple first-region segments to a second memory channel of the multiple memory channels; and transferring other data to the second memory channel based on the second first-region segment and in accordance with the first interleaving granularity.

Example 14: The method of example 13, or any one or more of the examples described herein, wherein the other data comprises at least one of: a boot image; or a firmware image.

Example 15: The method of example 1, or any one or more of the examples described herein, further comprising: transferring other debug data to the first memory channel based on the first first-region segment and in accordance with the first interleaving granularity, the other debug data comprising debug data besides the scandump data.

Example 16: An apparatus for implementing a scandump operation using at least one memory channel, the apparatus comprising: multiple memory channels; at least one memory configured to store processor-executable instructions; and one or more processors coupled to the multiple memory channels and the at least one memory, the one or more processors configured to execute the processor-executable instructions to: partition a logical address space into a first region and a second region; partition the first region into multiple first-region segments, each respective first-region segment of the multiple first-region segments corresponding to a respective memory channel of the multiple memory channels; assign a first first-region segment of the multiple first-region segments to a first memory channel of the multiple memory channels; institute a first interleaving granularity for the first region and a second interleaving granularity for the second region, the first interleaving granularity different from the second interleaving granularity; and transfer scandump data to the first memory channel based on the first first-region segment and in accordance with the first interleaving granularity.

Example 17: The apparatus of example 16, or any one or more of the examples described herein, wherein: the multiple memory channels include a first memory channel; the first memory channel comprises a first memory controller and a first physical memory coupled to the first memory controller; the one or more processors are configured to transfer the scandump data into the first physical memory via the first memory controller based on a size of the scandump data being less than the first interleaving granularity; the one or more processors comprise logic and a memory interleaver; and the at least one memory comprises at least one of hard-coded logic or a physical memory of the multiple memory channels.

Example 18: The apparatus of example 16, or any one or more of the examples described herein, wherein the one or more processors are configured to execute the processor-executable instructions to: store non-scandump data into a second first-region segment of the multiple first-region segments of the first region in accordance with the first interleaving granularity; partition the second region into multiple second-region segments, each respective second-region segment of the multiple second-region segments corresponding to a respective memory channel of the multiple memory channels; and store blocks of data across at least two second-region segments of the multiple second-region segments in an interleaved manner in accordance with the blocks of data being larger than the second interleaving granularity.

Example 19: An apparatus for implementing a scandump operation using at least one memory channel, the apparatus comprising: multiple memory channels comprising a first memory channel and a second memory channel; and one or more processors coupled to the multiple memory channels and configured to: partition a logical address space into a first region and a second region, the first region comprising multiple first-region segments, the second region comprising multiple second-region segments; store non-scandump data into the first memory channel based on a first first-region segment of the multiple first-region segments and in accordance with a first interleaving granularity corresponding to the first region; store data into the multiple memory channels in an interleaved manner based on multiple second-region segments and in accordance with a second interleaving granularity corresponding to the second region, the first interleaving granularity different from the second interleaving granularity; and transfer scandump data into the second memory channel based on a second first-region segment of the multiple first-region segments and in accordance with the first interleaving granularity corresponding to the first region.

Example 20: The apparatus of example 19, or any one or more of the examples described herein, wherein: the scandump data corresponds to circuitry that excludes the multiple memory channels; and the one or more processors are configured to cause the first memory channel to perform a scandump operation on the first memory channel in conjunction with the transfer of the scandump data into the second memory channel.

Features described in the context of one example aspect (e.g., a method or an apparatus) may be used in combination with other example aspects (e.g., an apparatus or a method, respectively, or a different method or a different apparatus).

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

Although implementations for realizing enhanced memory-channel-focused scandump have been described in language specific to certain features and/or methods, the subject of the appended claims is not necessarily limited to the specific features or methods described. Rather, the specific features and methods are disclosed as example implementations for realizing enhanced memory-channel-focused scandump.

What is claimed is:

1. A method for implementing a scandump operation using at least one memory channel, the method comprising:
partitioning a logical address space into a first region and a second region;
instituting a first interleaving granularity for the first region and a second interleaving granularity for the second region, the first interleaving granularity different from the second interleaving granularity;
partitioning the first region into multiple first-region segments, each respective first-region segment of the multiple first-region segments corresponding to a respective memory channel of multiple memory channels;
assigning a first first-region segment of the multiple first-region segments to a first memory channel of the multiple memory channels; and
transferring scandump data to the first memory channel based on the first first-region segment and in accordance with the first interleaving granularity.

2. The method of claim 1, wherein:
the first interleaving granularity is larger than the second interleaving granularity.

3. The method of claim 2, wherein:
the first interleaving granularity is at least three orders of magnitude larger than the second interleaving granularity.

4. The method of claim 2, wherein:
the first interleaving granularity is larger than a size of the scandump data transferred to the first memory channel.

5. The method of claim 4, wherein:
the scandump data comprises a logical state of targeted circuitry.

6. The method of claim 1, further comprising:
storing data in the multiple memory channels using the second region and in accordance with the second interleaving granularity.

7. The method of claim 6, further comprising:
partitioning the second region into multiple second-region segments, each respective second-region segment of the multiple second-region segments corresponding to a respective memory channel of the multiple memory channels.

8. The method of claim 7, wherein the storing data comprises:
storing the data in the multiple memory channels using the multiple second-region segments and in accordance with the second interleaving granularity.

9. The method of claim 8, wherein the storing the data comprises:
interleaving a block of related data across the multiple memory channels using the multiple second-region segments.

10. The method of claim 1, further comprising:
partitioning the second region into multiple second-region segments, each respective second-region segment of the multiple second-region segments corresponding to a respective memory channel of the multiple memory channels;
storing each first block of related data in its entirety within a single first-region segment of the multiple first-region segments based on each first block of related data being smaller than the first interleaving granularity; and
storing each second block of related data across at least two second-region segments of the multiple second-region segments in an interleaved manner based on each second block of related data being larger than the second interleaving granularity.

11. The method of claim 1, further comprising:
outputting the scandump data from the first memory channel after a recovery procedure has been performed.

12. The method of claim 1, further comprising:
generating other scandump data that corresponds to a logical state of a second memory channel of the multiple memory channels; and
transferring the other scandump data to at least one memory using a memory channel of the multiple memory channels, the memory channel excluding the second memory channel.

13. The method of claim 1, further comprising:
assigning a second first-region segment of the multiple first-region segments to a second memory channel of the multiple memory channels; and
transferring other data to the second memory channel based on the second first-region segment and in accordance with the first interleaving granularity.

14. The method of claim 13, wherein the other data comprises at least one of:
a boot image; or
a firmware image.

15. The method of claim 1, further comprising:
transferring other debug data to the first memory channel based on the first first-region segment and in accordance with the first interleaving granularity, the other debug data comprising debug data besides the scandump data.

16. An apparatus for implementing a scandump operation using at least one memory channel, the apparatus comprising:
multiple memory channels;
at least one memory configured to store processor-executable instructions; and
one or more processors coupled to the multiple memory channels and the at least one memory, the one or more processors configured to execute the processor-executable instructions to:
partition a logical address space into a first region and a second region;
partition the first region into multiple first-region segments, each respective first-region segment of the multiple first-region segments corresponding to a respective memory channel of the multiple memory channels;
assign a first first-region segment of the multiple first-region segments to a first memory channel of the multiple memory channels;
institute a first interleaving granularity for the first region and a second interleaving granularity for the second region, the first interleaving granularity different from the second interleaving granularity; and
transfer scandump data to the first memory channel based on the first first-region segment and in accordance with the first interleaving granularity.

17. The apparatus of claim 16, wherein:
the multiple memory channels include a first memory channel;
the first memory channel comprises a first memory controller and a first physical memory coupled to the first memory controller;
the one or more processors are configured to transfer the scandump data into the first physical memory via the first memory controller based on a size of the scandump data being less than the first interleaving granularity;
the one or more processors comprise logic and a memory interleaver; and
the at least one memory comprises at least one of hard-coded logic or a physical memory of the multiple memory channels.

18. The apparatus of claim 16, wherein the one or more processors are configured to execute the processor-executable instructions to:
store non-scandump data into a second first-region segment of the multiple first-region segments of the first region in accordance with the first interleaving granularity;
partition the second region into multiple second-region segments, each respective second-region segment of the multiple second-region segments corresponding to a respective memory channel of the multiple memory channels; and
store blocks of data across at least two second-region segments of the multiple second-region segments in an interleaved manner in accordance with the blocks of data being larger than the second interleaving granularity.

19. An apparatus for implementing a scandump operation using at least one memory channel, the apparatus comprising:
multiple memory channels comprising a first memory channel and a second memory channel; and
one or more processors coupled to the multiple memory channels and configured to:
partition a logical address space into a first region and a second region, the first region comprising multiple first-region segments, the second region comprising multiple second-region segments;
store non-scandump data into the first memory channel based on a first first-region segment of the multiple first-region segments and in accordance with a first interleaving granularity corresponding to the first region;
store data into the multiple memory channels in an interleaved manner based on multiple second-region segments and in accordance with a second interleaving granularity corresponding to the second region, the first interleaving granularity different from the second interleaving granularity; and
transfer scandump data into the second memory channel based on a second first-region segment of the multiple first-region segments and in accordance with the first interleaving granularity corresponding to the first region.

20. The apparatus of claim 19, wherein:
the scandump data corresponds to circuitry that excludes the multiple memory channels; and
the one or more processors are configured to cause the first memory channel to perform a scandump operation on the first memory channel in conjunction with the transfer of the scandump data into the second memory channel.
